(19) United States
(12) Patent Application Publication
(10) Pub. No.: US 2024/0379342 A1
(43) Pub. Date: Nov. 14, 2024

(54) METHOD FOR GRINDING SEMICONDUCTOR WAFERS

(71) Applicant: SILTRONIC AG, Munich (DE)

(72) Inventors: Stephan OBERHANS, Seeon (DE); Michael KERSTAN, Burghausen (DE); Robert WEISS, Winhoering (DE)

(21) Appl. No.: 18/686,906

(22) PCT Filed: Jul. 27, 2022
(86) PCT No.: PCT/EP2022/071093

§ 371 Date: Feb. 27, 2024

(30) Foreign Application Priority Data
Sep. 1, 2021 (EP) 21194262.8

(51) Int. Cl. H01L 21/02; B24B 7/22; B24B 37/04; B24B 37/08; B24B 55/02

(52) U.S. Cl. CPC H01L 21/02013; B24B 7/228; B24B 37/042; B24B 37/08; B24B 55/02

(57) ABSTRACT

A semiconductor wafer is processed by grinding the semiconductor wafer so as to remove material using a grinding tool while delivering a coolant into a contact region between the rotating semiconductor wafer and the grinding tool. The grinding tool has grinding teeth having a height. While grinding, first and second coolant flow rates are respectively applied onto first and second regions on one side of the semiconductor wafer by one or more nozzles. The first region is bounded by a lower right quadrant of the semiconductor wafer and the second region is bounded by a lower left quadrant. A ratio of the first coolant flow rate and a sum of the first coolant flow rate and the second coolant flow rate is no more than 35% and no less than 25%.

### CROSS REFERENCE TO RELATED APPLICATIONS

This application is a U.S. National Phase application under 35 U.S.C. § 371 of International Application No. PCT/EP2022/071093, filed on Jul. 27, 2022, and claims benefit to European Patent Application No. EP 21194262.8, filed on Sep. 1, 2021. The International Application was published in German on Mar. 9, 2023 as WO 2023/030774 A1 under PCT Article 21 (2).

### FIELD

The present disclosure is directed to grinding a wafer made from semiconductor material.

### BACKGROUND

For electronics, microelectronics, and micro-electromechanics, semiconductor wafers with extreme requirements for global and local planarity, one-side referenced local planarity (nanotopology), roughness and cleanness are required as starting materials (substrates). Semiconductor wafers are wafers of semiconductor materials, in particular compound semiconductors such as gallium arsenide or elemental semiconductors such as silicon and germanium.

Semiconductor wafers are produced in a multiplicity of successive process steps. The following production sequence is generally used:
1—producing a single-crystal semiconductor rod (crystal growth),
2—dividing the semiconductor rod into individual rod pieces,
3—separating the rod into individual wafers (inner diameter or wire sawing),
4—mechanical treatment of the wafers (lapping, grinding),
5—chemical treatment of the wafers (alkaline or acidic etching),
6—chemical-mechanical treatment of the wafers (polishing),
7—optionally, further coating steps (for example epitaxy, heat treatment).

The mechanical treatment of the semiconductor wafer serves to remove corrugations caused by the sawing, also to remove the surface layers damaged in terms of crystalline structure by the rougher sawing processes or contaminated by the sawing wire, and above all to globally planarize the semiconductor wafers. The mechanical treatment of the semiconductor wafer furthermore serves to produce a uniform thickness distribution, that is to say that the semiconductor wafers have a uniform thickness.

Lapping and surface grinding (single-disk, double-disk) are known as methods for mechanical treatment of the semiconductor wafers.

The technique of double-disk lapping of several semiconductor wafers at the same time has been known for a long time and is described, for example, in EP 547894 A1. In double-disk lapping, the semiconductor wafers are moved under a certain pressure, while delivering a suspension containing an abrasive substance between an upper and a lower working disk, which usually consist of steel and are provided with channels for the better distribution of the suspension, and removal of material is thereby achieved. The semiconductor wafer is guided by a carrier disk having recesses for holding the semiconductor wafers during the lapping, the semiconductor wafer being kept on a geometrical path by the carrier disk which is set in rotation by way of drive gears.

In single-disk grinding, the semiconductor wafer is held at the rear side on a chuck and planarized on the front side by a cup grinding wheel, with the chuck and grinding wheel rotating and a slow axial and radial rate of advance. Methods and devices for the single-disk surface grinding of a semiconductor wafer are known for example from U.S. Pat. No. 2,008,021 40 94 A1 or from EP 0 955 126 A2.

KR 2011 006 6282 A discloses a grinding wheel which, in order to improve the cooling efficiency, is equipped with at least one coolant delivery hole so that the coolant can be fed directly to a grinding tool.

In simultaneous double-disk grinding (sDDG), the semiconductor wafer is treated on both sides at the same time while floating freely between two grinding wheels mounted on opposing collinear spindles, and in this case is guided axially between a water cushion (hydrostatic principle) or air cushion (aerostatic principle) acting on the front and rear sides substantially freely from constraining forces and is radially loosely prevented from floating away by a surrounding thin guide ring or by individual radial spokes. Methods and devices for the simultaneous double-disk surface grinding of a semiconductor wafer are known for example from EP 0 755 751 A1, EP 0 971 398 A1, DE 10 2004 011 996 A1, and DE 10 2006 032 455 A1.

However, owing to the kinematics, double-disk grinding (DDG) of semiconductor wafers in principle causes removal of more material in the center of the semiconductor wafer (“grinding navel”). In order, after grinding, to obtain a semiconductor wafer with as good a geometry as possible, it is necessary for the two grinding spindles on which the grinding wheels are mounted to be aligned exactly collinearly, since radial and/or axial deviations have a negative influence on the shape and nanotopology of the wafer being ground. German application DE 10 2007 049 810 A1 teaches for example a method for correcting the grinding spindle position in double-disk grinding machines.

In grinding processes—this relates both to single-disk and to double-disk grinding methods—it is necessary to cool the grinding tool and/or the semiconductor wafer being treated. Water or deionized water is usually used as a coolant. In double-disk grinding machines, the coolant usually emerges from the center of the grinding tool and is transported or catapulted by way of centrifugal force to the grinding teeth that are arranged in a circular shape on the outer edge of the grinding wheel. The coolant throughput, that is to say the amount of coolant that emerges in a defined time, may be controlled electronically or mechanically.

Document DE 10 2007 030 958 A1 teaches a method for grinding semiconductor wafers in which the semiconductor wafers are treated so as to remove material on one side or both sides by way of at least one grinding tool, with a coolant being supplied. In order to ensure constant cooling during the grinding, the coolant flow rate is reduced as the grinding tooth height decreases, since a coolant flow kept high without being changed would otherwise inevitably lead to aquaplaning effects.

The disclosure in document DE 10 2017 215 705 A1 is based on the optimum distribution of a fluid in a grinding tool for treating a semiconductor wafer so as to remove material on both sides at the same time, this being achieved using an optimized skidding plate. It is taught here that an uneven distribution of the fluid has a negative effect on the grinding result.

Patent document US 2019/134782 A1 discloses certain designs of grinding wheels that may be used for double-disk grinding. It is also taught to use water that is applied from the inside onto the grinding teeth of the grinding wheel by way of a nozzle. Together with the grinding water, it flushes grinding abrasion and tool abrasion away from the treatment region.

### SUMMARY

In an embodiment, the present disclosure provides a method for grinding a semiconductor wafer so as to remove material using a grinding tool while delivering a coolant into a contact region between the rotating semiconductor wafer and the grinding tool. The grinding tool has grinding teeth having a height. While grinding, first and second coolant flow rates are respectively applied onto first and second regions on one side of the semiconductor wafer by one or more nozzles. The first region is bounded by a lower right quadrant of the semiconductor wafer and the second region is bounded by a lower left quadrant. A ratio of the first coolant flow rate and a sum of the first coolant flow rate and the second coolant flow rate is no more than 35% and no less than 25%.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows by way of example a device which may be used in order to apply the required amounts of coolant during the grinding process;

FIG. 2 shows two regions on the semiconductor wafer, to which the coolant is preferably applied in order to achieve the advantageous effect in terms of geometry; and

FIG. 3 shows two particularly preferred regions on a semiconductor wafer, to which the coolant may be applied in order to improve the geometry even further.

### DETAILED DESCRIPTION

The above-discussed state of the art has the common disadvantage that the removal of material is higher in the center of the semiconductor wafers than at the edge. The geometrical parameters of the semiconductor wafer in this treatment step are therefore degraded. This aberration cannot, or cannot sufficiently, be corrected in the subsequent treatment steps. The present inventors have, therefore, found that the quality of the geometry which can be achieved by means of grinding is insufficient with the methods which are known.

Aspects of the present disclosure provide a method that does not exhibit the abovementioned disadvantages. One or more aspects of the present disclosure are based on the optimum distribution of a fluid in the surroundings of the grinding tool in order to treat a semiconductor wafer so as to remove material from both sides at the same time.

According to one aspect of the present disclosure, there is provided a method for grinding a semiconductor wafer, the semiconductor wafer being processed so as to remove material by means of a grinding tool containing grinding teeth having a height h while delivering a coolant into a contact region between the rotating semiconductor wafer and the grinding tool, at each instant of the grinding, a first coolant flow rate being applied onto a first region on one side of the semiconductor wafer by means of one or more nozzles, and at each instant of the grinding, a second coolant flow rate being applied onto a second region on the one side of the semiconductor wafer by means of one or more nozzles, wherein the first region is bounded by the lower right quadrant of the semiconductor wafer and the second region is bounded by the lower left quadrant, and the ratio of the first coolant flow rate and the sum of the first and second coolant flow rates is no more than 35% and no less than 25%.

In a preferred embodiment, it is preferred for the semiconductor wafer to have a nominal diameter of 300 mm and for the sum of the coolant flow rates to be no less than 800 ml/min and no more than 1200 ml/min.

In a preferred embodiment, it is also preferred for both sides of the semiconductor wafer to be simultaneously processed so as to remove material.

In a preferred embodiment, it is likewise preferred for the sum of the coolant flow rates to be reduced with a decreasing height h.

In a preferred embodiment it is more particularly preferred for the first region to be an annular sector which has an annulus width w, a midpoint and an outer radius, and is bounded by a first straight line through the midpoint, which is inclined by the angle α with respect to the vertical symmetry axis of the semiconductor wafer, and is furthermore bounded by a second straight line through the midpoint, which is inclined by the angle β with respect to the vertical symmetry axis of the semiconductor wafer, and for the second region to be derived from the reflection of the first region through the vertical symmetry axis of the semiconductor wafer, the midpoint lying on the vertical symmetry axis of the semiconductor wafer and being no less than 75 mm away from the midpoint of the semiconductor wafer, the angle α being no less than 25°, the angle β being no less than 45°, the annulus width w being no less than 10 mm and no more than 25 mm, and the outer radius being no less than 80 mm and no more than 90 mm.

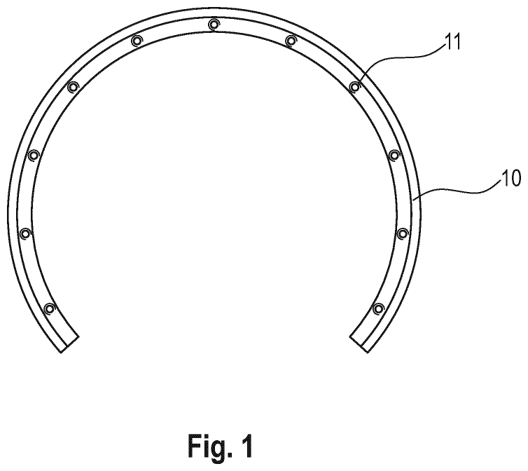

FIG. 1 shows by way of example a device (10) which may be used in order to apply the required amounts of coolant during the grinding process. Nozzles (11) are in this case fitted in such a way that they can apply the coolant onto the side to be ground of a semiconductor wafer. The nozzles can, in this case, be controlled separately from one another so that each nozzle can be operated with a throughput of coolant which is predefined and optionally varies as a function of time.

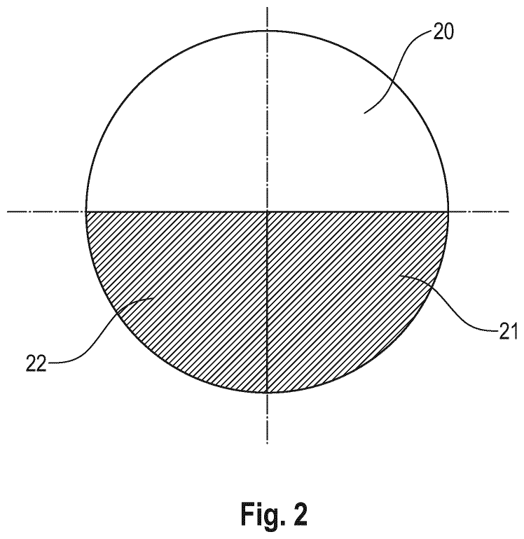

FIG. 2 shows two regions on the semiconductor wafer (20), to which the coolant is preferably applied in order to achieve the advantageous effect in terms of geometry. A first region (22), which lies in the lower right quadrant of the semiconductor wafer, and a second region (21), which lies in the lower left quadrant of the semiconductor wafer, are shown.

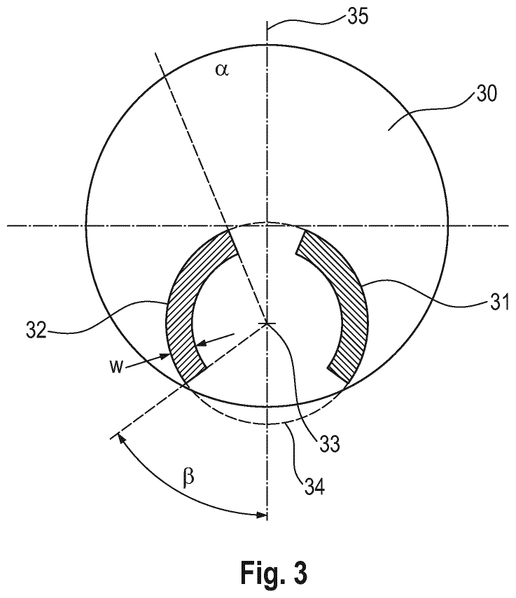

FIG. 3 shows two particularly preferred regions (shaded) on a semiconductor wafer (30), to which the coolant may be applied in order to improve the geometry even further. The first region (32) is an annular sector which has an annulus width w, a midpoint (33) and an outer radius. It is bounded by a first straight line through the midpoint (33), which is inclined by the angle α with respect to the vertical symmetry axis (35) of the semiconductor wafer (30). It is furthermore bounded by a second straight line through the midpoint (33), which is inclined by the angle β with respect to the vertical symmetry axis (35) of the semiconductor wafer. A second region (31) is furthermore shown, which is derived from the reflection of the first region (32) through the vertical symmetry axis (35) of the semiconductor wafer. The outer boundaries of the two regions lie on the circle (34) indicated.

The midpoint (33) lies on the vertical symmetry axis (35) of the semiconductor wafer (30) and at the same time lies below the horizontal symmetry axis of the semiconductor wafer.

There are many standardized measurement processes and measurement methods for assessing the geometry of semiconductor wafers. The Inventors have restricted themselves to assessing the semiconductor wafers by means of the parameters THA25 and warp.

Regarding THA25: In order to study the nanotopography, it is possible to use an interferometer, for example an instrument of the WaferSight™ type from KLA-Tencor Corp. Such an interferometer is suitable for measuring the topography on the upper side of a semiconductor wafer. The instrument forms a height map of the upper side of the semiconductor wafer, which is filtered and over which an analysis window having a defined analysis area is moved. The evaluation of the height differences in the analysis window is carried out by THA (“threshold height analysis”) according to the method specifications of the standards SEMI M43-0418 and SEMI M78-0618.

A warp measurement may, for example, be carried out according to SEMI MF 1390-0218.

Although optimally adjusted DDG machines make it possible to produce ground semiconductor wafers with improved shape, bow, warp and nanotopographies, it has however been found that the quality of these semiconductor wafers is not sufficient.

The Inventors have discovered that an improved geometry of the semiconductor wafer may be achieved by controlled delivery of a coolant, which takes place at defined regions of the semiconductor wafer during the grinding.

A piece of silicon crystal having a nominal diameter of 300 mm, which was obtained from a crystal rod pulled by using the Czochralski method, was cut into semiconductor wafers by way of a wire saw.

The semiconductor wafers were ground under different conditions in respect of the coolant flow rate on a grinding system of the Koyo DSGX320 type. The grinding system was in this case equipped with a commercially available grinding tool (grinding wheel) from the company ALMT, type #3000-OVH.

In double-disk grinding machines, the process coolant usually emerges from the center of the grinding tool and is transported by means of the centrifugal force to the grinding teeth. The coolant throughput may be regulated in such a way that the coolant flow rate can be kept at a setpoint value.

According to the state of the art, the amount of grinding water is delivered to the process while being regulated as a function of the tooth height (according to DE 10 2007 030 958 A1). This ensures that there is no floating, equivalent to aquaplaning, of the tool on the wafer to be treated when too much coolant is expelled outward from the inside of the tool during the process, and there is no overheating, equivalent to grinding burn, of the wafer to be treated and failure of the grinding wheel when there is too little coolant available in the process.

The Inventors have discovered that the distribution of the coolant over the semiconductor wafer has a significant effect on the outcome. In conventional grinding systems, for example, coolant is distributed by centrifugal forces over the semiconductor wafer to be ground, which is clearly not always sufficient to achieve a desired quality of the surface (planarity).

The Inventors have therefore developed a device, with the aid of which it is possible to apply coolant through a multiplicity of nozzles with both time and position resolution, both onto the front side and the backside of the semiconductor wafer.

FIG. 1 schematically shows a device which is suitable for applying coolant on a semiconductor wafer during the grinding.

The Inventors have succeeded in improving the method for grinding a semiconductor wafer by treating the semiconductor wafer so as to remove material by means of a grinding tool containing grinding teeth having a height h while delivering a coolant into a contact region between the rotating semiconductor wafer and the grinding tool.

At each instant of the grinding, a first coolant flow rate was applied onto a first region on one side of the semiconductor wafer by means of one or more nozzles.

At the same time, a second coolant flow rate was applied onto a second region on the one side of the semiconductor wafer by means of one or more nozzles.

It is particularly preferred for the first region to be bounded by the lower right quadrant of the semiconductor wafer and for the second region to be bounded by the lower left quadrant. According to a particularly preferred embodiment, the ratio of the first coolant flow rate and the sum of the first and second coolant flow rates should be no more than 35% and no less than 25%.

Preferably, the semiconductor wafer rotates during the grinding process. The rotation takes place in the clockwise sense, rotation in the clockwise sense being intended to mean as seen when observing the contact region on the semiconductor wafer.

The first and second regions are graphically represented in FIG. 2.

It is particularly preferable for the semiconductor wafer to have a nominal diameter of 300 mm and for the sum of the coolant flow rates to be no less than 800 ml/min and no more than 1200 ml/min.

It is more particularly preferred for both sides of the semiconductor wafer to be simultaneously processed so as to remove material.

It is also preferable for the sum of the coolant flow rates to be reduced with a decreasing height h of the grinding teeth.

FIG. 3 shows the regions in which the Inventors achieved the best results. The first region is in this case an annular sector which has an annulus width w, a midpoint and an outer radius, and is bounded by a first straight line through the midpoint, which is inclined by the angle α with respect to the vertical symmetry axis of the semiconductor wafer and is furthermore bounded by a second straight line through the midpoint, which is inclined by the angle β with respect to the vertical symmetry axis of the semiconductor wafer.

The second region is in this case derived from the reflection of the first region through the vertical symmetry axis of the semiconductor wafer, the midpoint lying on the vertical symmetry axis of the semiconductor wafer and being no less than 75 mm away from the midpoint of the semiconductor wafer.

Said angle α is preferably no less than 25° and the angle β is no less than 45°, and the annulus width w is preferably no less than 10 mm and no more than 25 mm and the outer radius is preferably no less than 80 mm and no more than 90 mm.

Water is preferably used as the coolant, although it is also conceivable for additives also to be used.

By the addition of the coolant, it has been found that the geometry of the wafer is improved significantly. If the flow of the coolant is interrupted during the grinding process, however, the geometry of the semiconductor wafer is also degraded again. It is therefore essential for the flow of the coolant not to be interrupted during the grinding.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for grinding a semiconductor wafer, the method comprising:
processing the semiconductor wafer so as to remove material by grinding with a grinding tool, the grinding tool comprising grinding teeth having a height h, while delivering a coolant into a contact region between the rotating semiconductor wafer and the grinding tool;
at each instant of the grinding, a first coolant flow rate is applied onto a first region on one side of the semiconductor wafer by one or more nozzles; and
at each instant of the grinding, a second coolant flow rate is applied onto a second region on the one side of the semiconductor wafer by one or more nozzles,
wherein the first region is bounded by a lower right quadrant of the semiconductor wafer and the second region is bounded by a lower left quadrant, and wherein a ratio of the first coolant flow rate and a sum of the first coolant flow rate and the second coolant flow rate is no more than 35% and no less than 25%.

2. The method as claimed in claim 1, wherein the semiconductor wafer has a nominal diameter of 300 mm, and wherein the sum of the first coolant flow rate and the second coolant flow rate is no less than 800 ml/min and no more than 1200 ml/min.

3. The method as claimed in claim 1, wherein the processing of the semiconductor by grinding comprises:
both sides of the semiconductor wafer being simultaneously processed so as to remove material.

4. The method as claimed in claim 1, wherein during the processing of the semiconductor wafer by grinding:
the semiconductor wafer is rotated, and the rotation takes place in the clockwise sense, the contact region being observed.

5. The method as claimed in claim 1, the method further comprising:
decreasing the sum of the first coolant flow rate and the second coolant flow rate with a decreasing height h.

6. The method as claimed in claim 1, wherein;
the first region is an annular sector, which has an annulus width w, a midpoint, and an outer radius, and is bounded by a first straight line through the midpoint, which is inclined by an angle α with respect to a vertical symmetry axis of the semiconductor wafer, and is furthermore bounded by a second straight line through the midpoint, which is inclined by an angle β with respect to the vertical symmetry axis of the semiconductor wafer, and
the second region is derived from a reflection of the first region through the vertical symmetry axis of the semiconductor wafer, and
the midpoint lies on the vertical symmetry axis of the semiconductor wafer and is no less than 75 mm away from the midpoint of the semiconductor wafer,
the angle α is no less than 25°,
the angle β is no less than 45°,
the annulus width w is no less than 10 mm and no more than 25 mm, and the outer radius is no less than 80 mm and no more than 90 mm.
